(19) United States
(12) Patent Application Publication
(10) Pub. No.: US 2025/0294716 A1
(43) Pub. Date: Sep. 18, 2025

(54) STATIC RANDOM ACCESS MEMORY DEVICE

(71) Applicant: Taiwan Semiconductor Manufacturing Company, Ltd., Hsinchu (TW)

(72) Inventors: Jui-Lin Chen, Taipei City (TW); Ping-Wei Wang, Hsin-Chu (TW); Yu-Bey Wu, Hsinchu City (TW); Yu-Kuan Lin, Taipei City (TW)

(21) Appl. No.: 18/744,306

(22) Filed: Jun. 14, 2024

Related U.S. Application Data
(60) Provisional application No. 63/564,628, filed on Mar. 13, 2024.

(51) Int. Cl. H10B 10/00; G11C 11/412; H01L 21/8234; H01L 23/522; H01L 23/528; H01L 23/532; H01L 27/088; H01L 29/06; H01L 29/08; H01L 29/423; H01L 29/66; H01L 29/78; H01L 29/786

(52) U.S. Cl. CPC H10B 10/12; H01L 23/5226; H01L 23/528; H01L 23/53266; H10D 30/024; H10D 30/62; H10D 30/6735; H10D 30/6757; H10D 62/121; H10D 62/151; H10D 84/013; H10D 84/0149; H10D 84/0158; H10D 84/038; H10D 84/834; G11C 11/412

(57) ABSTRACT

A semiconductor device according to the present disclosure includes a first transistor and a second transistor sharing a first source/drain feature, a third transistor and a fourth transistor sharing a second source/drain feature, a first source/drain contact disposed over the first source/drain feature, a second source/drain contact disposed over the second source/drain feature, a first backside via disposed below the first source/drain feature, and a second backside via disposed below the second source/drain feature. A gate structure of the first transistor is coupled to the second source/drain contact and a gate structure of the fourth transistor is coupled to the first source/drain contact.

### PRIORITY DATA

This application claims priority to U.S. Provisional Patent Application Ser. No. 63/564,628, filed Mar. 13, 2024, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Static random access memory (“SRAM”) generally refers to any memory or storage that can retain stored data only when power is applied. As integrated circuit (IC) technologies progress towards smaller technology nodes, multi-gate structures, such as fin-like field effect transistors (FinFETs) or gate-all-around (GAA) transistors, are integrated into SRAM cells to enhance performance.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit schematic of a four-transistor-two-resistor (4T2R) SRAM cell, according to various aspects of the present disclosure.

FIG. 2 is a top view of a 4T2R SRAM cell in a first configuration, according to various aspects of the present disclosure.

FIG. 3 is a fragmentary cross-sectional view of along cross-section A-A′ of the 4T2R SRAM cell in FIG. 2, according to various aspects of the present disclosure.

FIGS. 4-9 are fragmentary cross-sectional views of along cross-section B-B′ of the 4T2R SRAM cell in FIG. 2, according to various aspects of the present disclosure.

FIG. 10 is a top view of a 4T2R SRAM cell in a second configuration, according to various aspects of the present disclosure.

FIGS. 11-13 are fragmentary cross-sectional views of along cross-section B-B′ of the 4T2R SRAM cell in FIG. 10, according to various aspects of the present disclosure.

FIG. 14 is a circuit schematic of a four-transistor-two-capacitor (4T2C) SRAM cell, according to various aspects of the present disclosure.

FIG. 15 is a top view of a 4T2C SRAM cell in a first configuration, according to various aspects of the present disclosure.

FIGS. 16-18 are fragmentary cross-sectional views of along cross-section B-B′ of the 4T2C SRAM cell in FIG. 15, according to various aspects of the present disclosure.

FIG. 19 is a top view of a 4T2C SRAM cell in a second configuration, according to various aspects of the present disclosure.

FIGS. 20-22 are fragmentary cross-sectional views of along cross-section B-B′ of the 4T2C SRAM cell in FIG. 19, according to various aspects of the present disclosure.

FIG. 23 illustrates a schematic top view of an interface between a memory region and a logic device region in a semiconductor device, according to various aspects of the present disclosure.

FIG. 24 illustrates a flowchart of a method for forming 4T2R SRAM cells or 4T2C SRAM cells according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

Static Random Access Memory (SRAM) is a semiconductor memory that retains data in a static form as long as the memory has power. Compared to dynamic RAM (DRAM), SRAM is faster and more reliable and does not need to be refreshed. SRAM is widely used in many applications, such as a computer's cache memory and as part of the random access memory of digital-to-analog converter on a video card. As integrated circuit (IC) technologies progress towards smaller technology nodes, multi-gate structures, such as fin-like field effect transistors (FinFETs) or gate-all-around (GAA) transistors, are integrated into SRAM cells to enhance performance. Mainstream SRAM cells usually include 6 or more transistors to have a six transistor (6T), a seven transistor (7T), an eight transistor (8T), a nine transistor (9T), a ten transistor (10T), a twelve transistor (12T), a thirteen transistor (13T), or a fourteen transistor (14T) configuration. These SRAM configurations have a tendency to produce a large SRAM cell size, which makes it difficult to meet the growing demand for a larger memory capacity and a compact size in mobile application.

The present disclosure provides area efficient four-transistor-two-resistor (4T2R) SRAM cells or four-transistor-two-capacitor (4T2C) SRAM cells. According to the present disclosure, the load resistors in a 4T2R SRAM cell or the load capacitors in a 4T2C SRAM are implemented in or along with backside contacts that are coupled to a backside interconnect structure. Due to the compact design, active regions in an SRAM region may align with active regions in a logic circuit region. As a result, with adoption of the 4T2R SRAM cells or 4T2C SRAM cells of the present disclosure, an SRAM region and a logic circuit region may directly abut one another, eliminating the need to have a transition region between the two regions. Due to the compact design and the elimination of the transition region, adoption of the 4T2R SRAM cells or 4T2C SRAM cells of the present disclosure may reduce the SRAM cell dimensions by 15% to 30% and the SRAM macro dimensions by more than 50%.

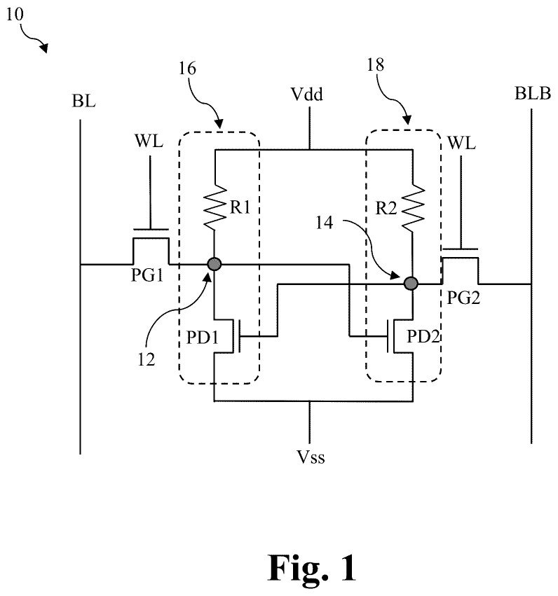

FIG. 1 is a circuit schematic of a four-transistor-two-resistor (4T2R) SRAM cell 10, according to various aspects of the present disclosure. The 4T2R SRAM cell 10 include four transistors and two load resistors. The four transistors are a first pass-gate transistor (PG1), a first pull-down transistor (PD1), a second pass-gate transistor (PG2), and a second pull-down transistor (PD2). The two load resistors are a first resistor R1 and a second resistor R2. As shown in FIG. 1, gates of the first and second pass-gate transistors PG1 and PG2 are electrically coupled to word-line (WL) that determines whether the 4T2R SRAM cell 10 is selected or not. The first pull-down transistor PD1 and the first resistor R1 form a first inverter 16. The second pull-down transistor PD2 and the second resistor R2 form a second inverter 18. The first and second inverters 16 and 18 are cross-coupled at first storage node 12 and a second storage node 14. Bits of data can be written into, or read from, the 4T2R SRAM cell 10 through bit-line (BL) and bit-line bar (BLB). In this arrangement, the BL and BLB may carry complementary bit-line signals. The 4T2R SRAM cell 10 is powered through a positive power supply voltage Vdd and is also connected to a ground potential Vss. The first resistor R1 is coupled to a source/drain of the first pull-down transistor (PD1) while the other source/drain of the first pull-down transistor (PD2) is coupled to the ground potential Vss. Similarly, the second resistor R2 is coupled to a source/drain of the second pull-down transistor (PD2) while the other source/drain of the second pull-down transistor (PD2) is coupled to the ground potential Vss.

Each of the four transistors in the 4T2R SRAM cell 10 in FIG. 1 may be implemented using a planar transistor or a multi-gate transistor, such as a fin-like FET (FinFET) or a gate-all-around (GAA) transistor. A GAA transistor may include channel regions of various shapes including nanowire, nanobar, or nanosheet, which may be collectively referred to as nanostructures. A GAA transistor may also be referred to as a multi-bridge-channel (MBC) transistor or a surrounding-gate-transistor (SGT). The four transistors in the 4T2R SRAM cell 10 may be either all n-type or all p-type. When all four transistors are n-type transistors, their source/drain features include silicon (Si) doped with an n-type dopant, such as phosphorus (P) and arsenic (As). When all four transistors are p-type transistors, their source/drain features include silicon germanium (SiGe) doped with a p-type dopant, such as boron (B) and boron difluoride (BF₂). Each of the first resistor R1 and the second resistor R2 is coupled to the positive power supply voltage Vdd. As will be described in more detail below, each of the first resistor R1 and the second resistor R2 is formed in or along with a backside contact that couples the first storage node 12 and the second storage node 14 to the positive power supply voltage Vdd. The positive power supply voltage Vdd is provided through a first backside metal layer or a second backside metal in a backside interconnect structure. Electrical connection to the word line (WL), ground voltage Vss, BL and BLB is provided through structures and contacts in a frontside interconnect structure. By having the two load resistors implemented in the backside contacts, the 4T2R SRAM cell 10 has smaller cell dimensions than SRAM cells with more transistors.

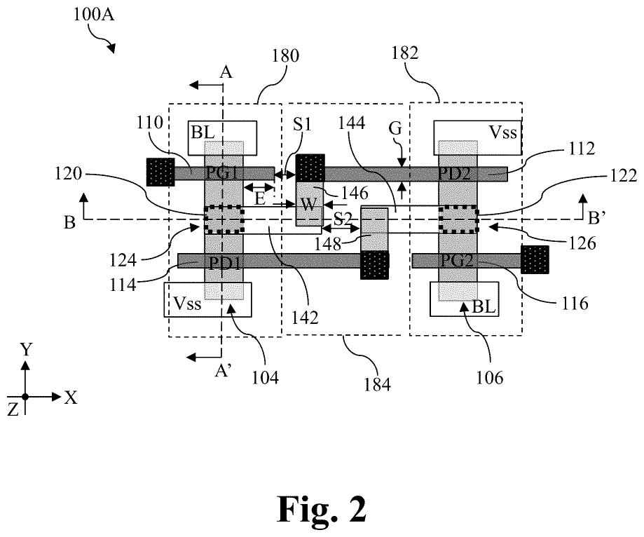

FIG. 2 is a top view of a 4T2R SRAM cell 100A in a first configuration. For avoidance of doubts, the 4T2R SRAM cell 100A represents a physical implementation of the 4T2R SRAM cell 10 shown in FIG. 1. In some embodiments represented in FIG. 2, the first pass-gate transistor PG1 and the first pull-down transistor PD1 are formed on a first active region 104 and the second pass-gate transistor PG2 and the second pull-down transistor PD2 are formed on a second active region 106. Depending on the design, each of the first active region 104 and the second active region 106 may include a semiconductor body defined in a dielectric layer (in case that the 4 transistors are planar devices), a fin type semiconductor structure (in case that the 4 transistors are FinFETs), or a vertical stack of nanostructures (in case that the 4 transistors are GAA devices). The first pass-gate transistor PG1 and the first pull-down transistor PD1 shared a first source/drain feature 124. The second pass-gate transistor PG2 and the second pull-down transistor PD2 shared a second source/drain feature 126. The first pass-gate transistor PG1 is controlled by a first gate 110. The second pull-down transistor PD2 is controlled by a second gate 112. As shown in FIG. 2, the first gate 110 and the second gate 112 may be patterned from a continuous gate structure that extends lengthwise along the X direction, perpendicular to the lengthwise direction of the first active region 104 and the second active region 106. Dielectric gate cut features are formed to isolate gate segments formed from a continuous gate structure. That is, the first gate 110 and the second gate 112 are aligned along the X direction and are spaced apart from one another by a dielectric gate cut feature. The first pull-down transistor PD1 is controlled by a third gate 114. The second pass-gate transistor PG2 is controlled by a fourth gate 116. As shown in FIG. 2, the third gate 114 and the fourth gate 116 may be patterned from a continuous gate structure that extends lengthwise along the X direction. That is, the third gate 114 and the fourth gate 116 are aligned along the X direction.

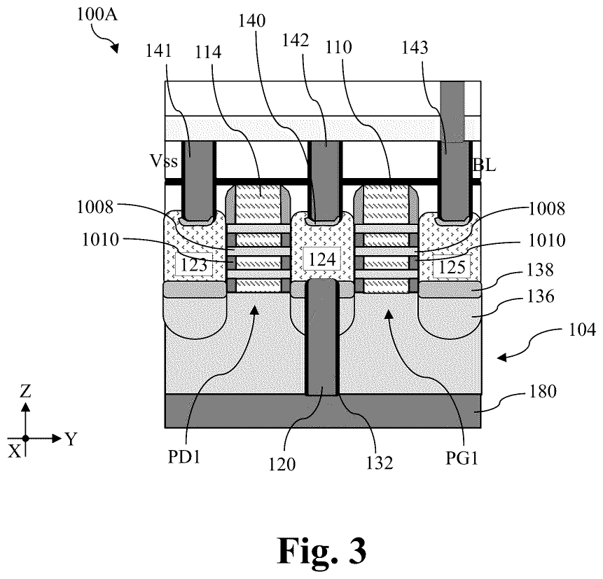

A first source/drain contact 142 is disposed over and coupled to the first source/drain feature 124. A second source/drain contact 144 is disposed over and coupled to the second source/drain feature 126. In some embodiments represented in FIG. 2, the first source/drain contact 142 extends toward the second source/drain feature 126 so as to be coupled to the second gate 112 by way of a first butted contact 146. Similarly, the second source/drain contact 144 extends toward the first source/drain feature 124 so as to be coupled to the third gate 114 by way of a second butted contact 148. In 4T2R SRAM cell 100A, a first backside contact 120 is disposed directly below the first source/drain feature 124 and a second backside contact 122 is disposed directly below the second source/drain feature 126. In other words, the first backside contact 120 and the second backside contact 122 are formed directly below the storage notes corresponding to storage nodes 12 and 14 shown in FIG. 1. In some embodiments, the first backside contact 120 is electrically coupled to a first backside power line 180 and the second backside contact 122 is electrically coupled to a second backside power line 182. In some instances, both the first backside power line 180 and the second backside power line 182 are disposed in a first backside metallization layer and are coupled to a metal line in a second backside metallization layer that carries the positive power supply voltage Vdd. In some alternative embodiments, the first backside contact 120 and the second backside contact 122 are coupled to a wide backside power line 184 that is wide enough such that both the first backside contact 120 and the second backside contact 122 land on it. In these alternative embodiments, the wide backside power line 184 is coupled to the positive power supply voltage Vdd. As will be described further in conjunction with FIGS. 3-9 below, a first resistor is formed between the first backside contact 120 and the first source/drain feature 124 and a second resistor is formed between the second backside contact 122 and the second source/drain feature 126. In some instances, an ion implantation of contact surfaces of the first source/drain feature 124 and the second source/drain feature 126 is omitted so as to increase the contact resistance. In some instances, a silicide layer at the interface is omitted so as to increase the contact resistance. In still some instances, a resistive layer is formed at the interface to increase resistance. In some further instances, a cross-sectional area of the backside contacts are reduced so as to increase contact resistance. In some other instances, both the first backside contact 120 and the second backside contact 122 are formed of a less conductive material, such as titanium nitride, tantalum nitride, or tungsten nitride. In some existing technology, efforts are invested to reduce the contact resistance of the backside contacts. However, in the present disclosure, the increased resistance associated with the backside contacts are embraced and used as load resistors in the 4T2R SRAM cell 100A.

Reference is still made to FIG. 2, which illustrates critical dimensional ranges. In some implementations, the first gate 110, the second gate 112, the third gate 114, and the fourth gate 116 extend lengthwise along the X direction and have a gate width G along the Y direction. To ensure that the first pass-gate transistor PG1 and the first pull-down transistor PD1 have substantially the same threshold voltage, the first gate 110 includes a gate extension E beyond a sidewall of the first active region 104. This gate extension E may also be referred to as a gate end cap. In some instances, a ratio (E/G) of the gate extension E and the gate width G may be between about 0.5 and about 1. When this ratio (E/G) is smaller than 0.5, the first pass-gate transistor PG1 may have a lower threshold voltage than the first pull-down transistor PD1, which impacts the read margin. When this ratio (E/G) is greater than 1, the memory cell dimension is unnecessarily enlarged and the threshold voltage benefit is diminished. As shown in FIG. 2, the first butted contact 146 and the second butted contact 148 extend lengthwise along the Y direction and include a contact with W along the X direction. In some embodiments, a ratio (W/G) of the contact with W and the gate width G may be between about 0.5 and about 1. When this ratio (W/G) is smaller than 0.5, the fill window to form the first butted contact 146 and the second butted contact 148 will be poor and voids may be present in the first butted contact 146 and the second butted contact 148. When this ratio (W/G) is greater than 1, the cost of cell size increase may outweigh the benefit of the enlarged fill window. As illustrated in FIG. 2, the first gate 110 and the second gate 112 may be spaced apart by a first spacing S1, which may be a width of a dielectric gate cut feature. In some instances, a ratio (S1/G) between the first spacing SI and the gate width G may be between about 0.5 and about 2. When this ratio (S1/G) is smaller than 0.5, the process window to isolate the first gate 110 and the second gate 112 may be too small, increasing risk of shorts. When this ratio (S1/G) is greater than 2, the first spacing SI may unduly increase the cell dimension without any benefits of reducing gate shorting. As illustrated in FIG. 2, the first source/drain contact 142 and the second source/drain contact 144 may be spaced apart by a second spacing S2. In some instances, a ratio (S2/G) between the second spacing S2 and the gate width G may be between about 0.5 and about 2. When this ratio (S2/G) is smaller than 0.5, the process window to isolate the first source/drain contact 142 and the second source/drain contact 144 may be too small, increasing risk of shorts. When this ratio (S2/G) is greater than 2, the second spacing S2 may unduly increase the cell dimension without any benefits of reducing source/drain contact shorting.

FIG. 3 is a fragmentary cross-sectional view of along cross-section A-A′ of the 4T2R SRAM cell 100A in FIG. 2. In some embodiments depicted in FIG. 3, all four transistors, including the first pull-down transistor PD1 and the first pass-gate transistor PG1 are GAA transistors. In FIG. 3, the first pull-down transistor PD1 includes a vertical stack of nanostructures 1008 disposed over the first active region 104 and the third gate 114 of the first pull-down transistor PD1 wraps around each of the nanostructures 1008. In some embodiments, the first active region 104 is a fin and may be referred to as a first base fin 104 as it is disposed below the vertical stack of nanostructures 1008. Similarly, the first pass-gate transistor PG1 also includes a vertical stack of nanostructures 1008 disposed over the first base fin 104 and the first gate 110 of the first pass-gate transistor PG1 wraps around each of the nanostructures 1008. The first gate 110 and the third gate 114 are spaced apart from adjacent source/drain features, such as the first source/drain feature 124 by a plurality of inner spacer features 1010. The plurality inner spacer features 1010 vertically interleave the vertical stack of nanostructures 1008. The nanostructures 1008 of the first pull-down transistor PD1 extend between the first source/drain feature 124 and a source/drain feature 123. The nanostructures 1008 of the first pass-gate transistor PG1 extend between the first source/drain feature 124 and a source/drain feature 125. In some embodiments where the first pull-down transistor PD1 and the pass-gate transistor PG1 are n-type, the source/drain feature 123, the first source/drain feature 124 and the source/drain feature 125 include silicon doped with an n-type dopant, such as phosphorus (P) or arsenic (As). In some alternative embodiments where the first pull-down transistor PD1 and the pass-gate transistor PG1 are p-type, the source/drain feature 123, the first source/drain feature 124 and the source/drain feature 125 include silicon germanium doped with a p-type dopant, such as boron (B) or boron difluoride (BF₂). In some embodiments, in order to form the source/drain features, a source/drain trench is first formed to extend partially into the first active region 104 (i.e., the first base fin 104). A bottom epitaxial layer 136 is then formed in the source/drain trench. In some instances, the bottom epitaxial layer 136 may include undoped silicon or undoped silicon germanium. In some embodiments represented in FIG. 3, a bottom isolation layer 138 is formed over the bottom epitaxial layer 136 to reduce leakage through the bottom epitaxial layer 136 and the first active region 104. In some embodiments, the bottom isolation layer 138 includes silicon nitride.

Referring still to FIG. 3, the first source/drain contact 142 engages a frontside surface of the first source/drain feature 124 by way of a silicide feature 140. In some embodiments, the first source/drain contact 142 includes cobalt (Co), copper (Cu), nickel (Ni), or a combination thereof. In some implementations, the silicide feature 140 may include titanium silicide, cobalt silicide, or nickel silicide. The silicide feature 140 functions to reduce contact resistance between the first source/drain contact 142 and the first source/drain feature 124. A source/drain contact 141, which is similar to the first source/drain contact 142 in terms of composition, is coupled to the source/drain feature 123 to bring the source/drain feature 123 to the ground potential Vss. Another source/drain contact 143, which is also similar to the first source/drain contact 142 in terms of composition, is coupled to the source/drain feature 125 and connects the same to a bit line (BL). In some embodiments represented in FIG. 3, the first backside contact 120 extends through the first base fin 104, the bottom epitaxial layer 136, and the bottom isolation layer 138 to couple to the first source/drain feature 124. In order to implement a load resistor, the first backside contact 120 makes contact a bottom surface of the first source/drain feature 124 without any silicide feature therebetween. In some other embodiments not illustrated in FIG. 3, one or more resistive materials may be deposited along the conduction path in order to increase or modulate resistance. In some embodiments, sidewalls of the first backside contact 120 may be lined with a dielectric liner 132. In some embodiments, the liner may include silicon nitride. As shown in FIG. 3, the dielectric liner 132 is removed from the interface between the first backside contact 120 and the first source/drain feature 124 such that the first backside contact 120 is resistively coupled to the first source/rain feature 124. In the depicted embodiments, except for the first backside contact 120 and the second backside contact 122, the other source/rain contacts, such as the first source/drain contact 142, the second source/drain contact 144, and source/drain contacts 141 and 143, are frontside contacts that extend downward to engage source/drain features in the 4T2R SRAM cell 100A.

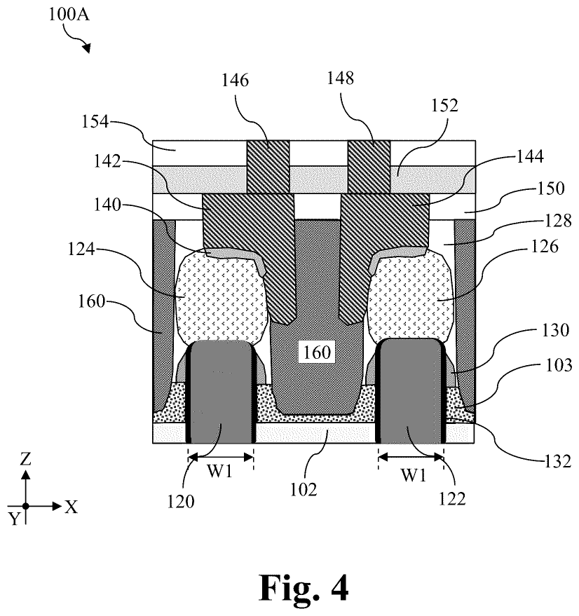

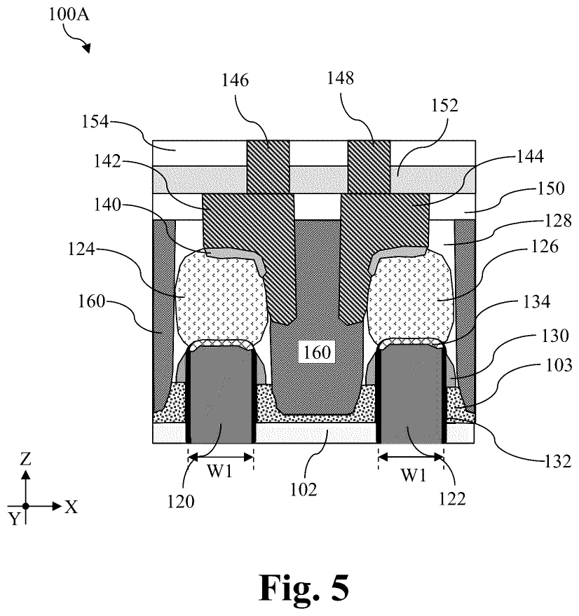

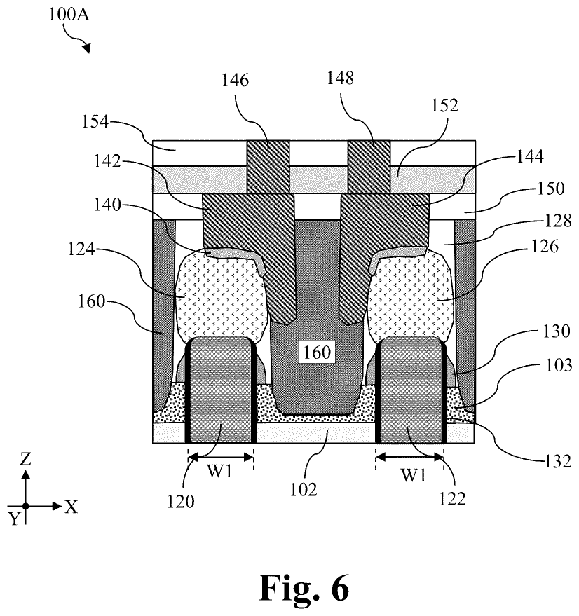

FIGS. 4-9 are fragmentary cross-sectional views of along cross-section B-B′ of the 4T2R SRAM cell 100A in FIG. 2. FIG. 4 illustrate a 4T2R SRAM cell 100A where the first backside contact 120 and the second backside contact 122 are disposed directly below the first source/drain feature 124 and the second source/drain feature 126. In embodiments represented in FIG. 4, the first backside contact 120 and the second backside contact 122 substantially displace the bottom isolation layer 138, the bottom epitaxial layer 136 under the first source/drain contact 142 and the second source/drain contact 144 to have a first width W1 along the X direction, which substantially correspond to a width of the first active region 104. In FIG. 4, the first backside contact 120 and the second backside contact 122 engages the first source/drain feature 124 and the second source/drain feature 126 without any intervening silicide layer, such as a titanium silicide layer. The omission of the silicide layer may increase the contact resistance and help turn the interfaces with the first backside contact 120 and the second backside contact 122 into the first load resistor R1 and the second load resistor R2. FIG. 5 illustrates an embodiment where a resistive layer 134 is formed that the interface to increase the contact resistance. In some instances, the resistive layer 134 may include tantalum silicide, zirconium silicide, chromium silicide, tantalum nitride, titanium nitride, or tungsten nitride. FIG. 6 illustrates an embodiment where an entirety of the first backside contact 120 and an entirety of the second backside contact 122 are formed of a conductive material that is less conductive than tungsten (W). In some instances, the first backside contact 120 and the second backside contact 122 may include tantalum nitride (TaN), tungsten nitride (WN), or titanium nitride (TiN). In one embodiment, the entirety of the first backside contact 120 and the second backside contact 122 include tantalum nitride (TaN).

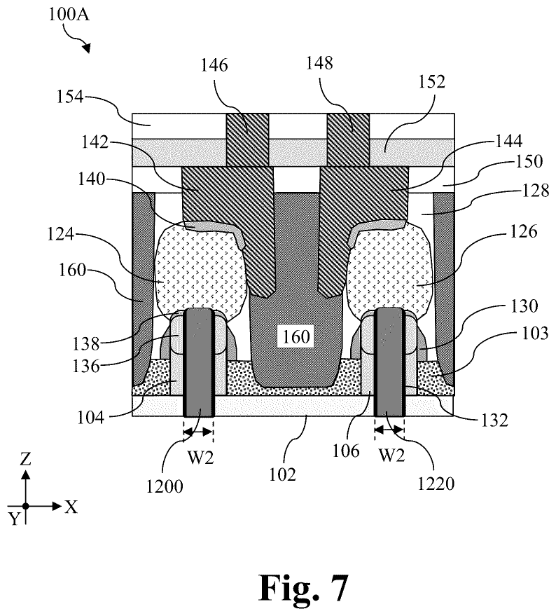

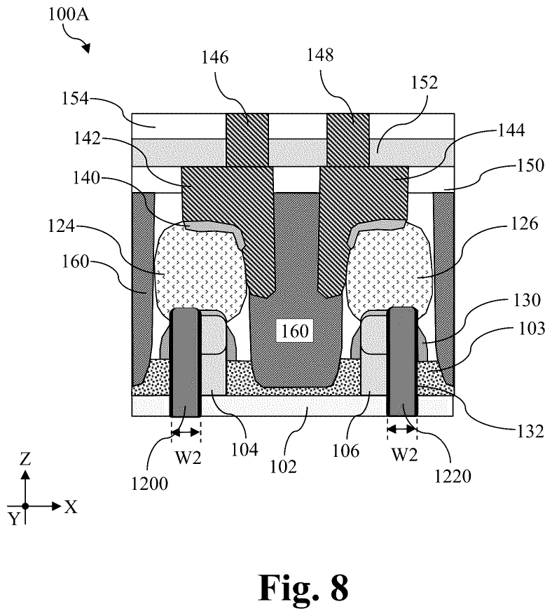

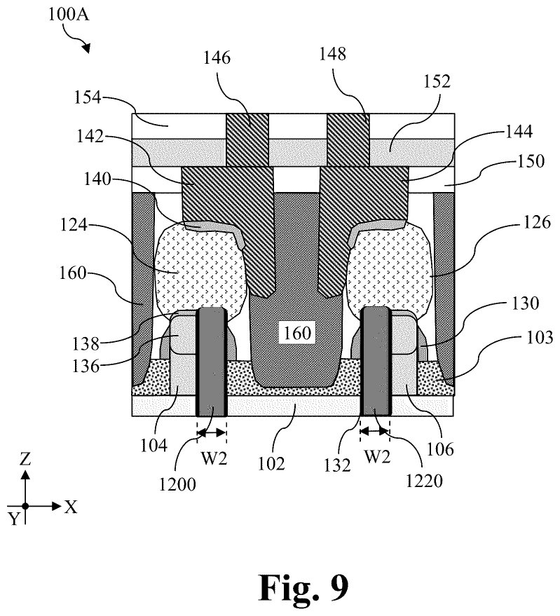

FIGS. 7-9 illustrate a 4T2R SRAM cell 100A where a narrow first source/drain contact 1200 and a narrow second source/drain contact 1220 are disposed directly below the first source/drain feature 124 and the second source/drain feature 126. The narrow first source/drain contact 1200 and the narrow second source/drain contact 1220 have a second width W2 along the X direction and the second width W2 is smaller than the first width W1. In some instances, a ratio of the second width W2 to the first width W1 is between about 0.2 and about 0.8, or between about 20% and about 80%. Embodiments shown in FIGS. 7-9 illustrate how dimensions or cross-sectional area of the first backside contact 120 and the second backside contact 122 can be used to adjust a resistance value of the first load resistor R1 and the second load resistor R2 in FIG. 1. In general, the silicide-free interface of the first backside contact 120 and the second backside contact 122 in FIG. 4 represent a base line of the resistance. By having a smaller second width W2, the silicide-free narrow first backside contact 1200 and the narrow second backside contact 1220 provide an increased resistance as they provide a smaller current conducting path. FIG. 7 represents an embodiment where the narrow first backside contact 1200 and the narrow second backside contact 1220 land share a same pitch with the first active region 104 and the second active region 106. FIG. 8 represents an embodiment where the narrow first backside contact 1200 and the narrow second backside contact 1220 land are farther apart from one another along the X direction. FIG. 9 represents an embodiment where the narrow first backside contact 1200 and the narrow second backside contact 1220 land are closer to one another one another along the X direction. It should be understood that the example embodiments shown in FIGS. 7-9 may be modified by introducing at the contact interface a resistive layer similar to the resistive layer 134 shown in FIG. 5 or by using a less conductive material, such tantalum nitride (TaN), tungsten nitride (WN), or titanium nitride (TiN), to form the entirety of the narrow first backside contact 1200 and the narrow second backside contact 1220.

Reference is made to FIGS. 4-9. Isolation fins 160 (or dielectric fins 160) may be formed to separate adjacent active regions and source/drain features. In FIGS. 4-9, an isolation fin 160 extends between the first active region 104 and the second active region 106 as well as between the first source/drain feature 124 and the second source/drain feature 126. In some embodiments, the first source/drain contact 142 engages a top surface of the first source/drain feature 124 and continues to extend over the isolation fin 160. As shown in FIGS. 4-9, a lower portion of the first source/drain contact 142 extend downward into the isolation fin 160 along a sidewall of the first source/drain feature 124. Similarly, the second source/drain contact 144 engages a top surface of the second source/drain feature 126 and continues to extend over the isolation fin 160. As shown in FIGS. 4-9, a lower portion of the second source/drain contact 144 extend downward into the isolation fin 160 along a sidewall of the second source/drain feature 126. The first source/drain contact 142 and the second source/drain contact 144 are spaced apart from one another by a portion of the isolation fin 160 and a portion of a second interlayer dielectric layer 150. Sidewalls of each of the first backside contact 120 and the second backside contact 122 are spaced apart from a backside dielectric layer 102 and the gate spacer 130 by a dielectric liner 132. In some instances, the dielectric liner 132 may include silicon nitride.

Reference is still made to FIGS. 4-9. In some example process, after the first source/drain feature 124 and the second source/drain feature 126 are formed. A first interlayer dielectric (ILD) layer 128 is deposited over the first source/drain feature 124 and the second source/drain feature 126 and planarized to have a planar top surface. After the formation of the first ILD layer 128, trenches are formed in the first ILD layer 128 and a dielectric material is deposited over the trenches. After another planarization process, a second interlayer dielectric (ILD) layer 150 is deposited over the first ILD layer 128. Openings for the first source/drain contact 142 and the second source/drain contact 144 are then formed through the dielectric fin, the second ILD layer 150 and the first ILD layer 128. In some embodiments, an etch stop layer 152 and a third ILD layer 154 are formed over the second ILD layer 150, the first source/drain contact 142 and the second source/drain contact 144. In some instances, the etch stop layer 152 may include silicon nitride, aluminum nitride, or aluminum oxide. The first ILD layer 128, the second ILD layer 150, and the third ILD layer 154 may include silicon oxide. A first butted contact 146 and the second butted contact 148 extend through the third ILD layer 154 and the etch stop layer 152 to couple to the first source/drain contact 142 and the second source/drain contact 144, respectively. As shown in FIG. 2, the first butted contact 146 electrically couples the first source/drain contact 142 to the second gate 112 and the second butted contact 148 electrically couples the second source/drain contact 144 to the third gate 114. In some embodiments, the first source/drain contact 142 and the second source/drain contact 144 may include tungsten (W), copper (Cu), cobalt (Co), nickel (Ni), or a combination thereof. In one embodiment, they include cobalt (Co). The first butted contact 146, the second butted contact 148, the first backside contact 120, the second backside contact 122, the narrow first backside contact 1200, and the narrow second backside contact 1220 may include tungsten (W) or copper (Cu). In one embodiment, they are formed of tungsten (W).

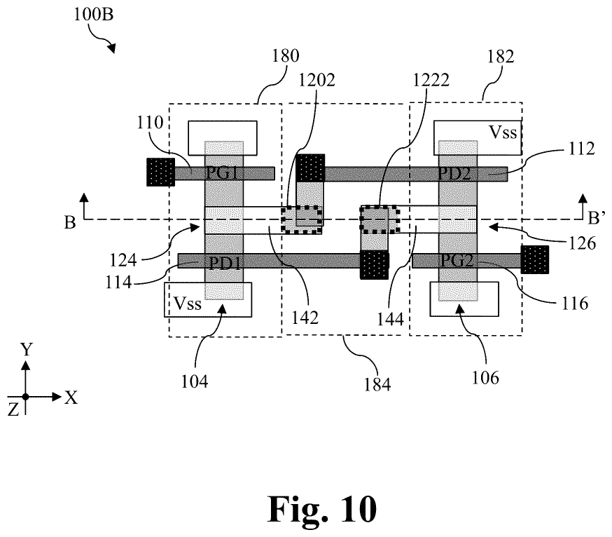

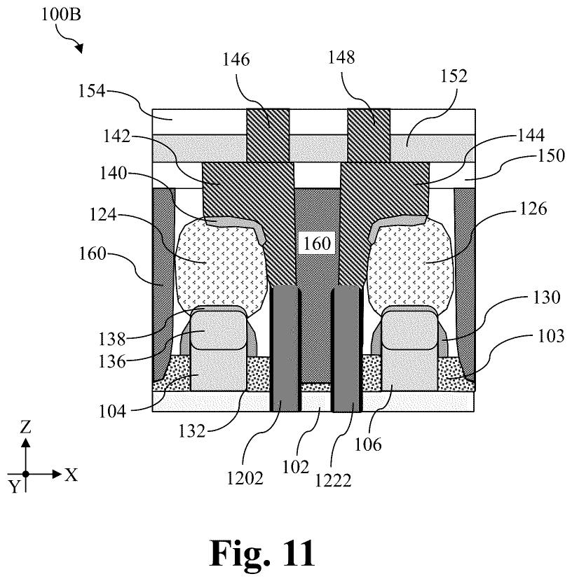

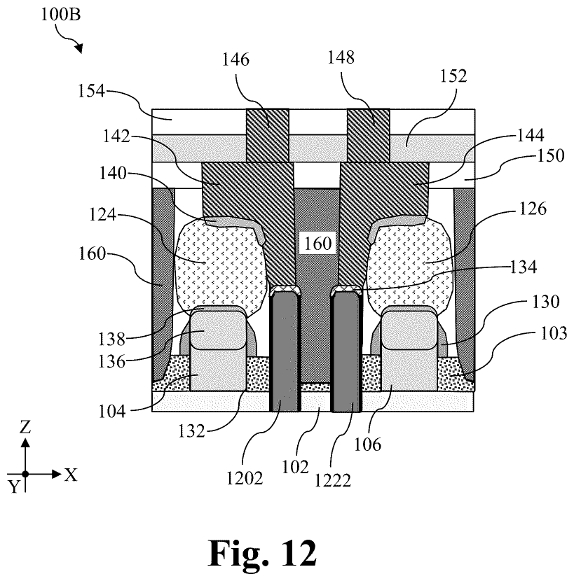

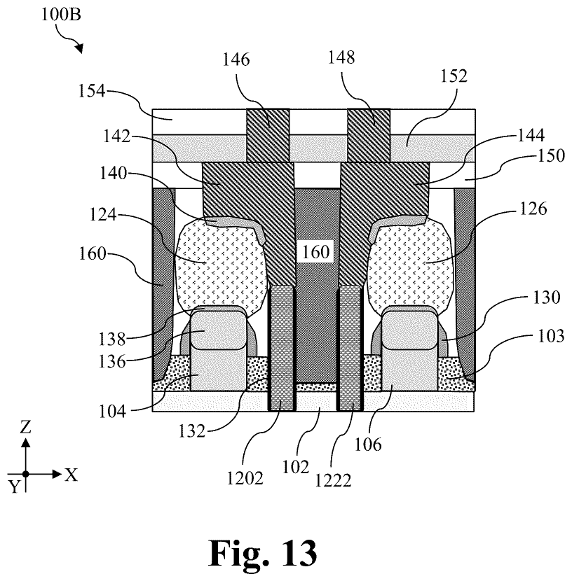

FIG. 10 is a top view of a 4T2R SRAM cell 100B in a second configuration. For avoidance of doubts, the 4T2R SRAM cell 100B also represents a physical implementation of the 4T2R SRAM cell 10 shown in FIG. 1. The 4T2R SRAM cell 100B in FIG. 10 is similar to the 4T2R SRAM cell 100A in FIG. 2 in many aspects, except that the first and second backside contacts 120 and 122 are replaced with a third backside contact 1202 and a fourth backside contact 1222. Different from the first and second backside contacts 120 and 122, the third backside contact 1202 and the fourth backside contact 1222 are not disposed directly below the first source/drain feature 124 and the second source/drain feature 126. Instead, vertical protections of the third backside contact 1202 and the fourth backside contact 1222 are offset toward the isolation fin 160 between the first source/drain feature 124 and the second source/drain feature 126. FIGS. 11-13 are fragmentary cross-sectional views of along cross-section B-B′ of the 4T2R SRAM cell 100B in FIG. 10. In some embodiments represented in FIG. 11, the third backside contact 1202 extends upward toward and is coupled to the lower portion of the first source/drain contact 142 and the fourth backside contact 1222 extends upward toward and is coupled to the lower portion of the second source/drain contact 144. In some implementations represented in FIG. 11, the third backside contact 1202 and the fourth backside contact 1222 engage the lower portions of the first source/drain contact 142 and the second source/drain contact 144 without any silicide feature in between to lower contact resistance, thereby for the first resistor R1 and the second resistor R2. In some implementations represented in FIG. 12, a resistive layer 134 is formed between the third backside contact 1202 and the fourth backside contact 1222 and the lower portions of the first source/drain contact 142 and the second source/drain contact 144. The resistive layer 134 is formed of a conductive material that is less conductive than tungsten (W). In some implementations, the resistive layer 134 may include tantalum silicide, zirconium silicide, chromium silicide, tantalum nitride, titanium nitride, or tungsten nitride. In some embodiments represented in FIG. 13, the entirety of the third backside contact 1202 and the fourth backside contact 1222 is formed of a conductive material less conductive than tungsten (W). For example, the entirety of the third backside contact 1202 and the fourth backside contact 1222 in FIG. 13 is formed of tantalum nitride (TaN), tungsten nitride (WN), or titanium nitride (TiN). In one embodiment, the entirety of the third backside contact 1202 and the fourth backside contact 1222 in FIG. 13 is formed of tantalum nitride (TaN).

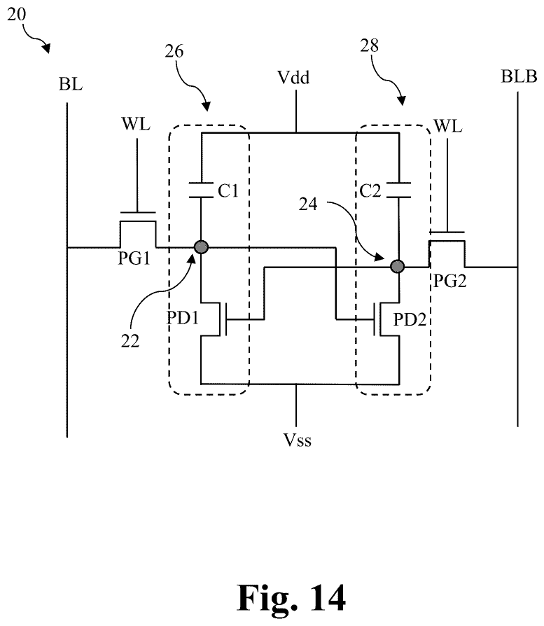

FIG. 14 is a circuit schematic of a four-transistor-two-capacitor (4T2C) SRAM cell 20, according to various aspects of the present disclosure. The 4T2C SRAM cell 20 include four transistors and two load capacitors. The four transistors are a first pass-gate transistor (PG1), a first pull-down transistor (PD1), a second pass-gate transistor (PG2), and a second pull-down transistor (PD2). The two load capacitors are a first capacitor C1 and a second capacitor C2. As shown in FIG. 14, gates of the first and second pass-gate transistors PG1 and PG2 are electrically coupled to word-line (WL) that determines whether the 4T2C SRAM cell 20 is selected or not. The first pull-down transistor PD1 and the first capacitor C1 form a first inverter 26. The second pull-down transistor PD2 and the second capacitor C2 form a second inverter 28. The first and second inverters 26 and 28 are cross-coupled at first storage node 22 and a second storage node 24. Bits of data can be written into, or read from, the 4T2C SRAM cell 20 through bit-line (BL) and bit-line bar (BLB). In this arrangement, the BL and BLB may carry complementary bit-line signals. The 4T2C SRAM cell 20 is powered through a positive power supply voltage Vdd and is also connected to a ground potential Vss. The first capacitor C1 is coupled to a source/drain of the first pull-down transistor (PD1) while the other source/drain of the first pull-down transistor (PD2) is coupled to the ground potential Vss. Similarly, the second capacitor C2 is coupled to a source/drain of the second pull-down transistor (PD2) while the other source/drain of the second pull-down transistor (PD2) is coupled to the ground potential Vss.

Each of the four transistors in the 4T2C SRAM cell 20 in FIG. 14 may be implemented using a planar transistor or a multi-gate transistor, such as a FinFET or a gate-all-around (GAA) transistor. Each of the four transistors in the 4T2C SRAM cell 20 may be either n-type or p-type. In some embodiments, in order to maximize drive current, all four transistors are n-type transistors. Each of the first capacitor C1 and the second capacitor C2 is coupled to the positive power supply voltage Vdd. As will be described in more detail below, each of the first capacitor C1 and the second capacitor C2 is formed in or along with a backside contact that couples the first storage node 22 and the second storage node 24 to the positive power supply voltage Vdd. The positive power supply voltage Vdd is provided through a first backside metal layer or a second backside metal in a backside interconnect structure. Electrical connection to the word line (WL), ground voltage Vss, BL and BLB is provided through structures and contacts in a frontside interconnect structure. By having the two load capacitors implemented in the backside contacts, the 4T2C SRAM cell 20 has smaller cell dimensions than SRAM cells with more transistors.

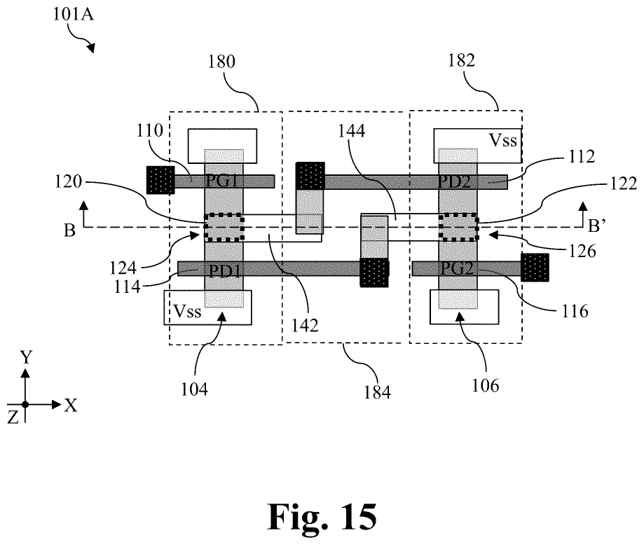

FIG. 15 is a top view of a 4T2C SRAM cell 101A in a first configuration. The 4T2C SRAM cell 101A is similar to the 4T2R SRAM cell 100A shown in FIG. 2, except that the 4T2C SRAM cell 101A includes two load capacitors implemented in or along with the first backside contact 120 and the second backside contact 122. Detailed description of the 4T2C SRAM cell 101A is omitted for brevity. The critical dimensional ratios described above in conjunction with FIG. 2 generally apply to the 4T2C SRAM cell 101A in FIG. 15.

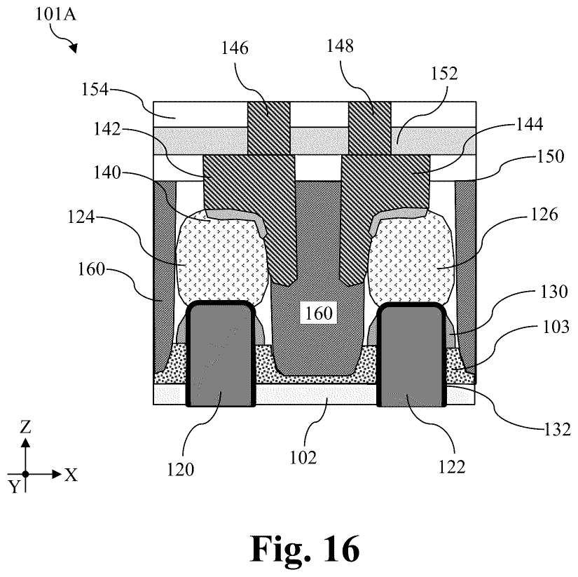

FIGS. 16-18 are fragmentary cross-sectional views of along cross-section B-B′ of the 4T2C SRAM cell 101A in FIG. 15. Cross-sections B-B′ in FIGS. 12-15 are similar to the cross-section B-B′ in FIG. 4, except that one or more dielectric layers are disposed vertically between the first backside contact 120 and the first source/drain feature 124 as well as vertically between the second backside contact 122 and the second source/drain feature 126. Reference is first made to FIG. 16. The dielectric liner 132 does not only extend along sidewalls of the first backside contact 120 and the second backside contact 122 but also along top surfaces of the first backside contact 120 and the second backside contact 122. The liner 132 between backside contact (i.e., the first backside contact 120 or the second backside contact 122) and the source/drain feature (i.e., the first source/drain feature 124 or the second source/drain feature 126) constitutes a metal-insulator-metal (MIM) capacitor. The first backside contact 120, the first source/drain feature 124 and the dielectric liner 132 therebetween form the first capacitor C1. The second backside contact 122, the second source/drain feature 126 and the liner 132 therebetween form the second capacitor C2.

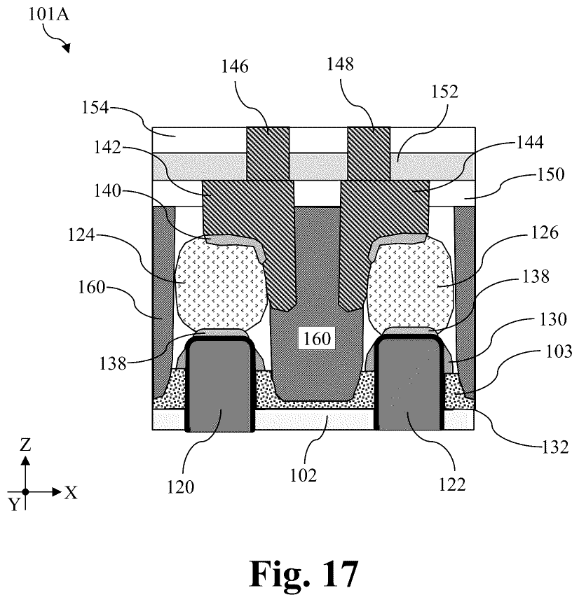

Reference is first made to FIG. 17. In some embodiments, at least a portion of the bottom isolation layer 138 is not etched through when openings for the first backside contact 120 and the second backside contact 122 are formed. In addition, a portion of the dielectric liner 132 also extends along top surfaces of the first backside contact 120 and the second backside contact 122. The dielectric liner 132 and the bottom isolation layer 138 between backside contact (i.e., the first backside contact 120 or the second backside contact 122) and the source/drain feature (i.e., the first source/drain feature 124 or the second source/drain feature 126) constitutes a metal-insulator-metal (MIM) capacitor. The liner 132 and the bottom isolation layer 138 between the first backside contact 120 and the first source/drain feature 124 serve as the dielectric material of the first capacitor C1. The liner 132 and the bottom isolation layer 138 between the second backside contact 122 and the second source/drain feature 126 serve as the dielectric material of the second capacitor C2. In some implementations, both the bottom isolation layer 138 and the liner 132 may include silicon nitride.

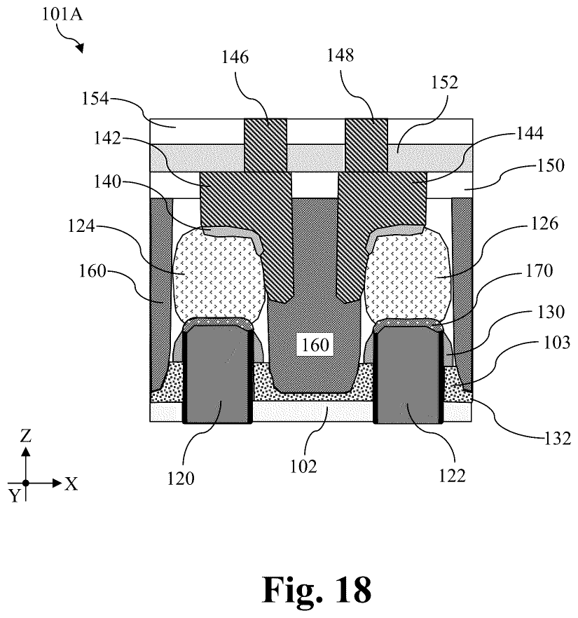

Reference is then made to FIG. 18. In some embodiments represented in FIG. 18, a ferroelectric cap layer 170 is deposited in the openings for the first backside contact 120 and the second backside contact 122 before the first backside contact 120 and the second backside contact 122 are formed. The ferroelectric cap layer 170 may include a suitable crystalline phase to exhibit ferroelectricity. In some embodiments, the ferroelectric cap layer 170 includes hafnium oxide, zirconium oxide, aluminum scandium nitride, or a combination thereof. In some instances, the ferroelectric cap layer 170 has a thickness between about 5 nm and about 20 nm. In FIG. 18, the dielectric liner 132 does not extend along top surfaces of the first backside contact 120 and the second backside contact 122. However, in some alternative embodiments, the liner 132 may extend between the backside contacts and the ferroelectric cap layer 170. The backside contact (i.e., the first backside contact 120 or the second backside contact 122) and the source/drain feature (i.e., the first source/drain feature 124 or the second source/drain feature 126) and the ferroelectric cap layer 170 therebetween constitutes a metal-insulator-metal (MIM) capacitor. The first backside contact 120, the first source/drain feature 124 and the liner 132 therebetween form the first capacitor C1. The second backside contact 122, the second source/drain feature 126 and the liner 132 therebetween form the second capacitor C2.

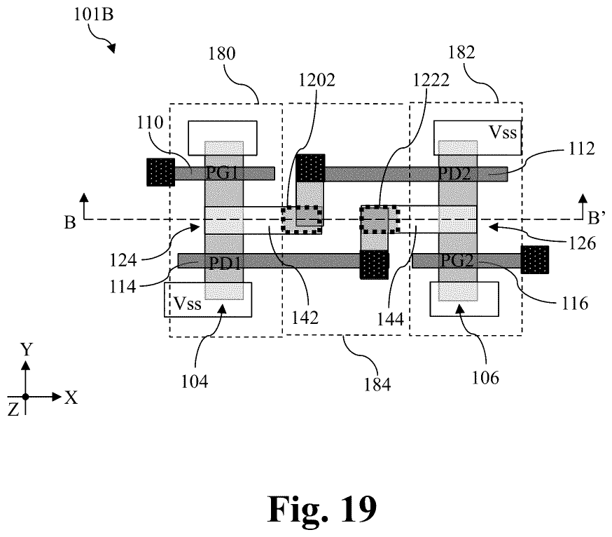

FIG. 19 is a top view of a 4T2C SRAM cell 101B in a second configuration. The 4T2C SRAM cell 101B is similar to the 4T2R SRAM cell 100B shown in FIG. 10, except that the 4T2C SRAM cell 101B includes two load capacitors implemented in or along with the third backside contact 1202 and the fourth backside contact 1222. Detailed description of the 4T2C SRAM cell 101B is omitted for brevity.

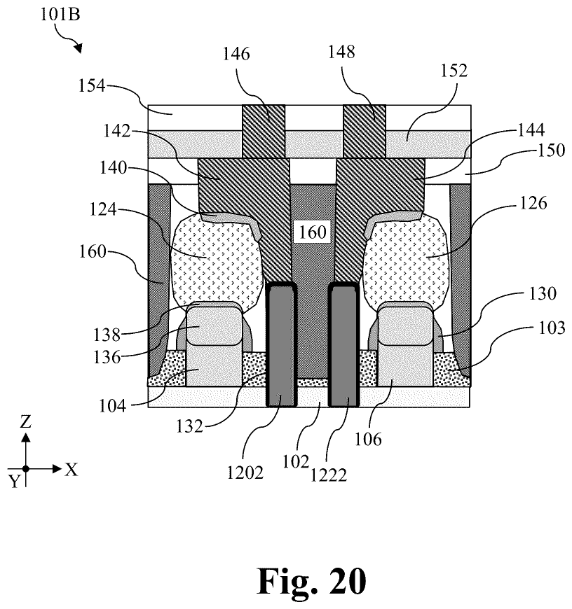

FIGS. 20-22 are fragmentary cross-sectional views of along cross-section B-B′ of the 4T2C SRAM cell 101B in FIG. 19. Cross-sections B-B′ in FIGS. 20-22 are similar to the cross-section B-B′ in FIG. 11, except that one or more dielectric layers are disposed vertically between third backside contact 1202 and the first source/drain contact 142 as well as vertically between the fourth backside contact 1222 and the second source/drain contact 144. Reference is first made to FIG. 20. The base fin 104, the bottom epitaxial layer 136, and the bottom isolation layer 138 between the first source/drain feature 124 or the second source/drain feature 126 remain intact. The third backside contact 1202 and the fourth backside contact 1222 extend through the backside dielectric layer 102, upward into the isolation structure 103, the isolation fin 160, and then toward the lower portions of the first source/drain contact 142 and the second source/drain contact 144. The liner 132 not only extends along sidewalls of the first backside contact 120 and the second backside contact 122 but also along top surfaces of the first backside contact 120 and the second backside contact 122. The liner 132 between backside contact (i.e., the first backside contact 120 or the second backside contact 122) and the source/drain feature (i.e., the first source/drain feature 124 or the second source/drain feature 126) constitutes a metal-insulator-metal (MIM) capacitor. The third backside contact 1202, the first source/drain feature 124 and the liner 132 therebetween form the first capacitor C1. The fourth backside contact 1222, the second source/drain feature 126 and the liner 132 therebetween form the second capacitor C2.

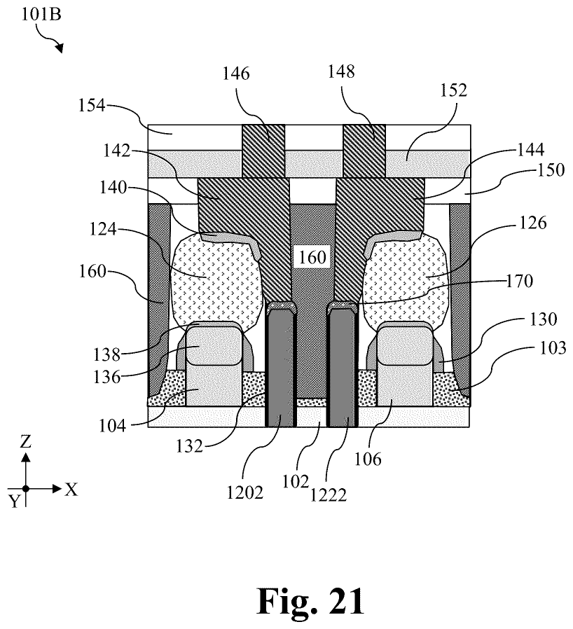

Reference is then made to FIG. 21. In some embodiments represented in FIG. 21, a ferroelectric cap layer 170 is deposited in the openings for the third backside contact 1202 and the fourth backside contact 1222 before the third backside contact 1202 and the fourth backside contact 1222 are formed. The ferroelectric cap layer 170 may include a suitable crystalline phase to exhibit ferroelectricity. In some embodiments, the ferroelectric cap layer 170 includes hafnium oxide, zirconium oxide, aluminum scandium nitride, or a combination thereof. In some instances, the ferroelectric cap layer 170 has a thickness between about 5 nm and about 20 nm. In FIG. 21, the liner 132 does not extend along top surfaces of the third backside contact 1202 and the fourth backside contact 1222. However, in some alternative embodiments, the liner 132 may extend between the narrow backside contacts and the ferroelectric cap layer 170. The backside contact (i.e., the third backside contact 1202 or the fourth backside contact 1222) and the source/drain contact (i.e., the first source/drain contact 142 or the second source/drain contact 144) and the ferroelectric cap layer 170 therebetween constitutes a metal-insulator-metal (MIM) capacitor. The third backside contact 1202, the first source/drain contact 142 and the ferroelectric cap layer 170 therebetween form the first capacitor C1. The fourth backside contact 1222, the second source/drain contact 144 and the ferroelectric cap layer 170 therebetween form the second capacitor C2.

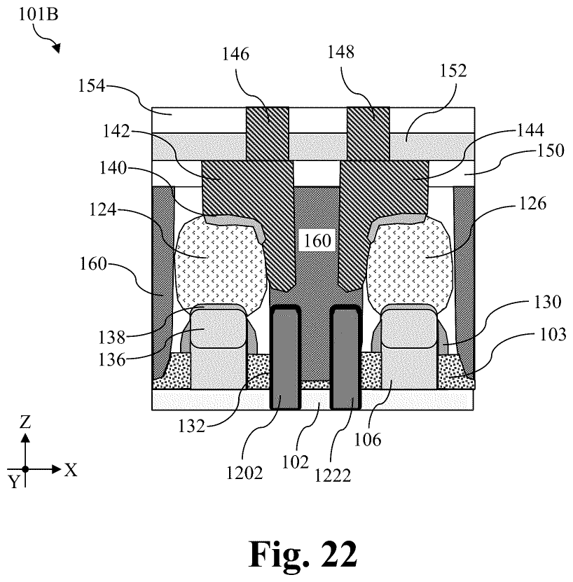

Reference is made to FIG. 22. In some embodiments represented in FIG. 22, the openings for the third backside contact 1202 and the fourth backside contact 1222 fall short of reaching the lower portions of the first source/drain contact 142 and the second source/drain contact 144. After the third backside contact 1202 and the fourth backside contact 1222 are formed, top surfaces of the third backside contact 1202 and the fourth backside contact 1222 remain spaced apart from the lower portions of the first source/drain contact 142 and the second source/drain contact 144 by a portion of the isolation fin 160. In addition, as shown in FIG. 22, the liner 132 extend along top surfaces of the third backside contact 1202 and the fourth backside contact 1222 The backside contact (i.e., the third backside contact 1202 or the fourth backside contact 1222) and the source/drain contacts (i.e., the first source/drain contact 142 or the second source/drain contact 144) as well as the isolation fin 160 and the liner 132 therebetween constitutes a metal-insulator-metal (MIM) capacitor. The third backside contact 1202, the first source/drain contact 142 as well as the liner 132 and the isolation fin 160 therebetween form the first capacitor C1. The fourth backside contact 1222, the narrow second source/drain contact 144 as well as the liner 132 and the isolation fin 160 therebetween form the second capacitor C2.

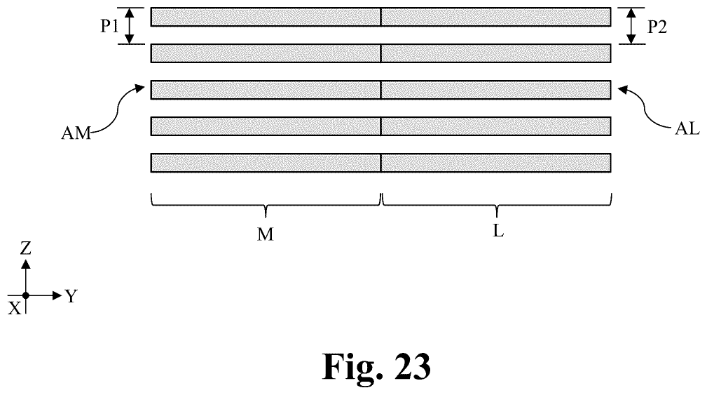

Adoption of the 4T2R or 4T2C SRAM cells of the present disclosure not only may lead to reduction of memory cell dimensions but may also result in reduction or elimination of transition regions between a memory device region and an adjacent logic device region. In some existing technologies, a memory cell may include different dimensions of active regions for transistors of different conductivity types. As a result, active regions in an existing memory cell do not share the same pitch with active regions in a nearby logic device region. In order to form proper electrical connection between the existing memory cell and the nearby logic device region, a transition region as wide as 4 to 12 gate pitches is inserted between the existing memory cell and the logic device region. Insertion of such a transition region will increase the macro dimension substantially. Adoption of the 4T2R or 4T2C SRAM cells of the present disclosure may completely remove the need of such transition region. FIG. 23 illustrates a schematic top view of an interface between a memory device area M and a logic device area L in a semiconductor device.

As shown in FIG. 23, the memory device area M includes a plurality of memory active regions AM and the logic device area L includes a plurality of logic active regions LM. Each of the memory active regions AM and the logic active regions LM may include a semiconductor body, a semiconductor fin structure, or a stack of nanostructures stacked vertically over a base fin structure. When the 4T2R or 4T2C SRAM cells of the present disclosure are adopted, each of the memory active regions AM may be aligned with one of the logic active regions LM. That is, due to adoption of the 4T2R or 4T2C SRAM cells of the present disclosure, the memory region M may directly abut the logic device region L. No transition region will be needed. It is noted that the logic device region L may be a region for logic devices, input/output devices, or peripheral devices.

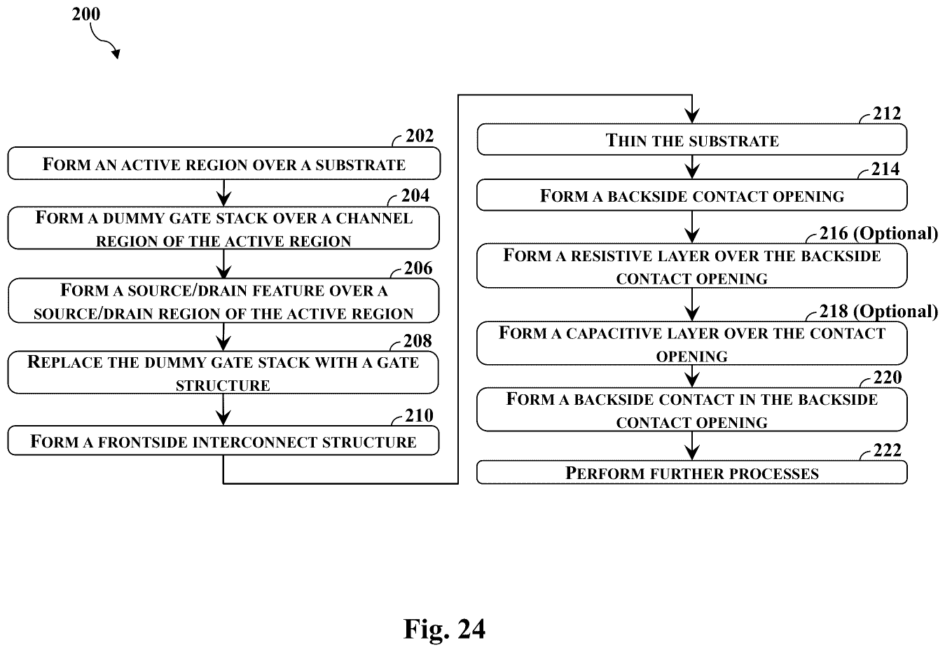

FIG. 24 illustrates a flowchart of a method 200 for forming 4T2R SRAM cells or 4T2C SRAM cells according to various aspects of the present disclosure. Method 200 includes blocks 202, 204, 206, 208, 210, 212, 214, 216, 218, 220, and 222. Depending on properties of the load resistors and load capacitors, operations at blocks 216 and 218 may be optional. At block 202, an active region, such as the first active region 104 or the second active region 106 shown in FIGS. 2, 3, 10, 15, and 19, is formed over a substrate, such as a silicon substrate. At block 204, a dummy gate stack is formed over a channel region of the active region. In some embodiments, a gate replacement process (or a gate-last process) may be adopted and a polysilicon dummy gate is formed as a placeholder to go through formation of source/drain features. The polysilicon dummy gate is subsequently replaced with a high-k metal gate structure, such as the first gate 110, the second gate 112, the third gate 114, and the fourth gate 116 shown in FIGS. 2, 3, 10, 15, and 19. While the dummy gate stack includes polysilicon, each of the first gate 110, the second gate 112, the third gate 114, and the fourth gate 116 includes an interfacial layer, a high-k dielectric layer, at least one work function metal layer, and a gate fill layer. In some embodiments, the interfacial layer includes silicon oxide, the high-k dielectric layer includes hafnium oxide, the at least one work function metal layer may include titanium nitride (TiN) or titanium aluminum (TiAl), and the gate fill layer may include tungsten (W). At block 204, a gate spacer layer is deposited over the dummy gate stack. At block 206, source/drain features are formed over source/drain regions of the active region. In an example process, the active region and the dummy gate stack is subject to an anisotropic etching after the formation of the gate spacer layer. As a result, source/drain regions of the active region are recessed to have source/drain trenches. Epitaxial deposition processes are performed to form source/drain features of the source/drain trenches. When the SRAM cell includes n-type devices, the source/drain features may include silicon (Si) and an n-type dopant, such as phosphorus (P) or arsenic (As). When the SRAM cell includes p-type devices, the source/drain features may include silicon germanium (SiGe) and a p-type dopant, such as boron (B) and boron difluoride (BF₂).

At block 208, the dummy gate stack is replaced with a high-k metal gate structure. After formation of the source/drain features over the source/drain regions, a contact etch stop layer (CESL) and an interlayer dielectric (ILD) layer are deposited over the source/drain features. A planarization process, such as a chemical mechanical polishing (CMP) process is performed to expose the dummy gate stacks. The dummy gate stacks are then selectively etched away and replaced with the high-k metal gate structure, such as the first gate 110, the second gate 112, the third gate 114, and the fourth gate 116 shown in FIGS. 2, 3, 10, 15, and 19. At block 210, a frontside interconnect structure is formed over the high-k metal gate structure. At block 210, source/drain contacts, such as the first source/drain contact 142 and the second source/rain contact 144 shown in FIGS. 2, 4-9, 11-13, and 15-22 are formed over memory cells. Additionally, butted contacts, such as the first butted contact 146 and the second butted contact 148, are formed over the source/drain contacts. While not shown in the figures, another 8 to 20 metallization layers may be formed over the butted contacts. The 8 to 20 metallization layers may be referred to as the frontside interconnect structure. In order to couple the devices to a backside interconnect structure, the substrate is thinned using mechanical grinding and polishing steps at block 212 In some examples, the substrate may have an initial thickness between about 750 μm and about 800 μm and the thinning at block 212 may reduce the thickness of the substrate to less than 100 μm, such as between 40 μm and about 80 μm. Block 214 includes formation of a backside contact openings. In some embodiments, a portion of the thinned substrate is removed and replaced with a bottom dielectric layer, such the backside dielectric layer 102. In some embodiments, the bottom dielectric layer may include silicon oxide. At block 214, an etch process selective to the bottom epitaxial layer 136 is used to form openings for backside contact openings. Alternatively, at block 214, narrow backside contact openings may be formed through the isolation structure 103 and the isolation fin 160, not through the bottom epitaxial layer 136. At block 216, when a 4T2R SRAM cell is desired, a resistive layer may be deposited over the backside contact openings. The resistive layer may include tantalum nitride, tungsten nitride, or titanium nitride. In some alternative embodiments, operations at block 216 are omitted when 4T2C SRAM cells are desired or when the source of the resistance is not the resistive layer. At block 218, when a 4T2R SRAM cell is desired, a capacitive layer may be formed over the contact opening. As described above, the capacitive layer formed at block 218 may include a ferroelectric cap layer, such as the ferroelectric cap layer 170 shown in FIGS. 18 and 21.

At block 220, a backside contact is formed in the backside contact opening. In some embodiments, a liner, such as the liner 132 shown in FIGS. 3-5, 7-9, 11-12, 16-18, and 20-22 is first formed in the backside contact opening. As described above, the liner 132 may include silicon nitride. At block 222, further processes may be performed. For example, operations at block 222 may include those required to form the backside interconnect structure.

In one example aspect, the present disclosure provides a semiconductor device. The semiconductor device includes a first transistor and a second transistor sharing a first source/drain feature, a third transistor and a fourth transistor sharing a second source/drain feature, a first source/drain contact disposed over the first source/drain feature, a second source/drain contact disposed over the second source/drain feature, a first backside via disposed below the first source/drain feature, and a second backside via disposed below the second source/drain feature. A gate structure of the first transistor is coupled to the second source/drain contact and a gate structure of the fourth transistor is coupled to the first source/drain contact.

In some embodiments, the first backside via and the second backside via include tungsten. An interface between the first backside via and the first source/drain feature and an interface between the second backside via and the second source/drain feature are free of a metal silicide. In some embodiments, the semiconductor device further includes a first dielectric liner disposed between the first backside via and the first source/drain feature, and a second dielectric liner disposed between the second backside via and the second source/drain feature. In some embodiments, the first dielectric liner and the second dielectric liner include silicon nitride. IN some embodiments, the first dielectric liner extends along sidewalls of the first backside via and the second dielectric liner extends along sidewalls of the second backside via. In some embodiments, the semiconductor device further includes a first bottom isolation layer disposed between the first dielectric liner and the first source/drain feature, and a second bottom isolation layer disposed between the second dielectric liner and the second source/drain feature. In some embodiments, the first transistor includes a first plurality of nanostructures and the gate structure of first transistor wraps around each of the first plurality of nanostructures. In some embodiments, the semiconductor device further includes a first resistive layer disposed between the first backside via and the first source/drain feature, and a second resistive layer disposed between the second backside via and the second source/drain feature. The first resistive layer and the second resistive layer include tantalum silicide, zirconium silicide, chromium silicide, tantalum nitride, titanium nitride, or tungsten nitride. In some implementations, the semiconductor device further includes a first ferroelectric layer disposed between the first backside via and the first source/drain feature, and a second ferroelectric layer disposed between the second backside via and the second source/drain feature.

Another aspect of the present disclosure pertains to a semiconductor device. The semiconductor device includes a backside dielectric layer, a first fin and a second fin disposed over the backside dielectric layer, a first source/drain feature disposed over the first fin, a second source/drain feature disposed over the second fin, an isolation structure disposed between the first fin and the second fin as well as between the first source/drain feature and the second source/drain feature, a first frontside contact disposed over the first source/drain feature and a first portion of the isolation structure, a second frontside contact disposed over the second source/drain feature and a second portion of the isolation structure, a first backside via extending along a sidewall of the first fin toward the first frontside contact, and a second backside via extending along a sidewall of the second fin toward the second frontside contact.

In some embodiments, the first backside via and the second backside via include tantalum nitride, tungsten nitride, or titanium nitride. In some embodiments, the first source/drain feature and the second source/drain feature include silicon and an n-type dopant. In some embodiments, the semiconductor device further includes a first resistive layer disposed between the first backside via and the first frontside contact, and a second resistive layer disposed between the second backside via and the second frontside contact. The first resistive layer and the second resistive layer include tantalum silicide, zirconium silicide, chromium silicide, tantalum nitride, titanium nitride, or tungsten nitride. In some embodiments, the semiconductor device further includes a first ferroelectric layer disposed between the first backside via and the first frontside contact, and a second ferroelectric layer disposed between the second backside via and the second frontside contact. In some implementations, the first ferroelectric layer and the second ferroelectric layer include hafnium oxide, zirconium oxide, or aluminum scandium nitride.

Yet another aspect of the present disclosure pertains to a semiconductor structure. The semiconductor structure includes a first pull-down transistor and a first pass-gate transistor sharing a first source/drain feature, a second pass-gate transistor and a second pull-down transistor sharing a second source/drain feature, a first source/drain contact disposed over the first source/drain feature, a second source/drain contact disposed over the second source/drain feature, a first backside via disposed below the first source/drain feature, and a second backside via disposed below the second source/drain feature. A gate structure of the first pull-down transistor is coupled to the second source/drain contact and a gate structure of the second pull-down transistor is coupled to the first source/drain contact.

In some embodiments, the first backside via and the second backside via include tungsten and an interface between the first backside via and the first source/drain feature and an interface between the second backside via and the second source/drain feature are free of a metal silicide. In some embodiments, the semiconductor structure further includes a first dielectric liner disposed between the first backside via and the first source/drain feature, and a second dielectric liner disposed between the second backside via and the second source/drain feature. In some implementations, the semiconductor structure further includes a first resistive layer disposed between the first backside via and the first source/drain feature, and a second resistive layer disposed between the second backside via and the second source/drain feature. The first resistive layer and the second resistive layer include tantalum silicide, zirconium silicide, chromium silicide, tantalum nitride, titanium nitride, or tungsten nitride. In some embodiments, the semiconductor structure further includes a first ferroelectric layer disposed between the first backside via and the first source/drain feature, and a second ferroelectric layer disposed between the second backside via and the second source/drain feature.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a first transistor and a second transistor sharing a first source/drain feature;
a third transistor and a fourth transistor sharing a second source/drain feature;
a first source/drain contact disposed over the first source/drain feature;
a second source/drain contact disposed over the second source/drain feature;
a first backside via disposed below the first source/drain feature; and
a second backside via disposed below the second source/drain feature,
wherein a gate structure of the first transistor is coupled to the second source/drain contact,
wherein a gate structure of the fourth transistor is coupled to the first source/drain contact.

2. The semiconductor device of claim 1,
wherein the first backside via and the second backside via comprise tungsten,
wherein an interface between the first backside via and the first source/drain feature and an interface between the second backside via and the second source/drain feature are free of a metal silicide.

3. The semiconductor device of claim 1, further comprising:
a first dielectric liner disposed between the first backside via and the first source/drain feature; and
a second dielectric liner disposed between the second backside via and the second source/drain feature.

4. The semiconductor device of claim 3, wherein the first dielectric liner and the second dielectric liner comprise silicon nitride.

5. The semiconductor device of claim 3,
wherein the first dielectric liner extends along sidewalls of the first backside via,
wherein the second dielectric liner extends along sidewalls of the second backside via.

6. The semiconductor device of claim 3, further comprising:
a first bottom isolation layer disposed between the first dielectric liner and the first source/drain feature; and
a second bottom isolation layer disposed between the second dielectric liner and the second source/drain feature.

7. The semiconductor device of claim 1,
wherein the first transistor comprises a first plurality of nanostructures,
wherein the gate structure of first transistor wraps around each of the first plurality of nanostructures.

8. The semiconductor device of claim 1, further comprising:
a first resistive layer disposed between the first backside via and the first source/drain feature; and
a second resistive layer disposed between the second backside via and the second source/drain feature,
wherein the first resistive layer and the second resistive layer comprise tantalum silicide, zirconium silicide, chromium silicide, tantalum nitride, titanium nitride, or tungsten nitride.

9. The semiconductor device of claim 1, further comprising:
a first ferroelectric layer disposed between the first backside via and the first source/drain feature; and
a second ferroelectric layer disposed between the second backside via and the second source/drain feature.

10. A semiconductor device, comprising:
a backside dielectric layer;
a first fin and a second fin disposed over the backside dielectric layer;
a first source/drain feature disposed over the first fin;
a second source/drain feature disposed over the second fin;
an isolation structure disposed between the first fin and the second fin as well as between the first source/drain feature and the second source/drain feature;
a first frontside contact disposed over the first source/drain feature and a first portion of the isolation structure;
a second frontside contact disposed over the second source/drain feature and a second portion of the isolation structure;
a first backside via extending along a sidewall of the first fin toward the first frontside contact; and
a second backside via extending along a sidewall of the second fin toward the second frontside contact.

11. The semiconductor device of claim 10, wherein the first backside via and the second backside via comprise tantalum nitride, tungsten nitride, or titanium nitride.

12. The semiconductor device of claim 11, wherein the first source/drain feature and the second source/drain feature comprise silicon and an n-type dopant.

13. The semiconductor device of claim 10, further comprising:
a first resistive layer disposed between the first backside via and the first frontside contact; and
a second resistive layer disposed between the second backside via and the second frontside contact,
wherein the first resistive layer and the second resistive layer comprise tantalum silicide, zirconium silicide, chromium silicide, tantalum nitride, titanium nitride, or tungsten nitride.

14. The semiconductor device of claim 10, further comprising:
a first ferroelectric layer disposed between the first backside via and the first frontside contact; and
a second ferroelectric layer disposed between the second backside via and the second frontside contact.

15. The semiconductor device of claim 14, wherein the first ferroelectric layer and the second ferroelectric layer comprise hafnium oxide, zirconium oxide, or aluminum scandium nitride.

16. A semiconductor structure, comprising:
a first pull-down transistor and a first pass-gate transistor sharing a first source/drain feature;
a second pass-gate transistor and a second pull-down transistor sharing a second source/drain feature;
a first source/drain contact disposed over the first source/drain feature;
a second source/drain contact disposed over the second source/drain feature;
a first backside via disposed below the first source/drain feature; and
a second backside via disposed below the second source/drain feature,
wherein a gate structure of the first pull-down transistor is coupled to the second source/drain contact,
wherein a gate structure of the second pull-down transistor is coupled to the first source/drain contact.

17. The semiconductor structure of claim 16,
wherein the first backside via and the second backside via comprise tungsten,
wherein an interface between the first backside via and the first source/drain feature and an interface between the second backside via and the second source/drain feature are free of a metal silicide.

18. The semiconductor structure of claim 16, further comprising:
a first dielectric liner disposed between the first backside via and the first source/drain feature; and
a second dielectric liner disposed between the second backside via and the second source/drain feature.

19. The semiconductor structure of claim 16, further comprising:
a first resistive layer disposed between the first backside via and the first source/drain feature; and
a second resistive layer disposed between the second backside via and the second source/drain feature,
wherein the first resistive layer and the second resistive layer comprise tantalum silicide, zirconium silicide, chromium silicide, tantalum nitride, titanium nitride, or tungsten nitride.

20. The semiconductor structure of claim 16, further comprising:
a first ferroelectric layer disposed between the first backside via and the first source/drain feature; and
a second ferroelectric layer disposed between the second backside via and the second source/drain feature.
